(19) United States
(12) Patent Application Publication
(10) Pub. No.: US 2016/0211424 A1
(43) Pub. Date: Jul. 21, 2016

(54) BLUE LIGHT-EMITTING PHOSPHOR AND LIGHT EMITTING DEVICE USING SAME

(71) Applicant: UBE MATERIAL INDUSTRIES, LTD., Ube-shi (JP)

(72) Inventors: Kouichi FUKUDA, Ube-shi (JP); Jin AMAGAI, Ube-shi (JP); Seiji NOGUCHI, Ube-shi (JP); Toru INAGAKI, Ube-shi (JP); Masaki TANAKA, Ube-shi (JP)

(21) Appl. No.: 15/083,942

(22) Filed: Mar. 29, 2016

Related U.S. Application Data
(63) Continuation of application No. 14/001,532, filed on Jan. 9, 2014.

(30) Foreign Application Priority Data
Feb. 28, 2011 (JP) 2011-042280

(51) Int. Cl. H01L 33/50; C09K 11/77

(52) U.S. Cl. CPC H01L 33/502; C09K 11/7792

(57) ABSTRACT

A blue light-emitting Eu-activated silicate phosphor having a constitutional formula of Sr₃MgSi₂O₈ which contains Eu in an amount of 0.001 to 0.2 mol per one mole of Mg and further a rare earth metal element selected from the group consisting of Sc, Y, Gd, Tb and La in an amount of 0.0001 to 0.03 mol, per one mole of Mg, gives an emission with enhanced emission strength when it is excited with a light having a wavelength in the region of 350 to 430 nm.

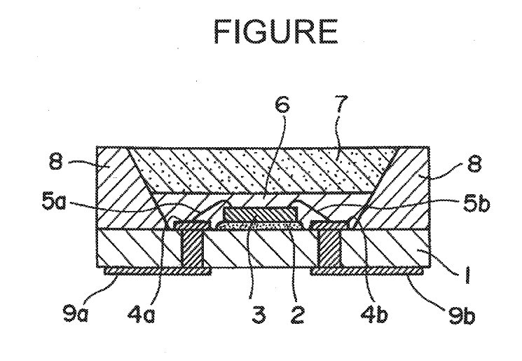

### FIELD OF THE INVENTION

The present invention relates to a blue light-emitting silicate phosphor having a constitutional formula of Sr₃MgSi₂O₈ activated with Eu. The invention further relates to a light-emitting device using the blue light-emitting phosphor as a blue light-emitting source.

### BACKGROUND OF THE INVENTION

There is known a blue light-emitting silicate phosphor having formula of Sr₃MgSi₂O₈ activated with Eu, which is named a blue light-emitting SMS phosphor.

D1(JP 48-37715 B) discloses a blue light-emitting SMS phosphor having formula of 3(Sr₁₋ₚ.Euₚ) O.MgO.2SiO₂. D1 describes that the SMS phosphor emits blue light when it is excited with a light source having a wavelength of 253.7 nm.

D2(JP 2006-312654 A) discloses a phosphor having the following formula:

3(M¹₁₋ₓEuₓ)O.mM²O.nM³O₂

wherein M¹ is at least one element selected from the group consisting of Ca, Sr and Ba, M² is Mg and/or Zn, M³ is Si and/or Ge, m is a value satisfying the condition of 0.9≦m≦1.1, n is a value satisfying the condition of 1.8≦n≦2.2, and x is a value satisfying the condition of 0.00016≦x<0.003.

The above-mentioned formula may embrace the blue light-emitting SMS phosphor. However, D2 mentions only to phosphors comprising Ba and Sr, Ba and Ca, Sr and Ca, or Ba, Sr and Ca.

D2 further describes the above-mentioned phosphor may contain a metal element such as Al, Sc, Y, La, Gd, Ce, Pr, Nd, Sm, Tb, Dy, Ho, Er, Tm, Yb, Lu, Bi or Mn. It is described that the phosphor containing the metal element in an amount of not less than 100 ppm and not more than 50,000 ppm may give a light emission of enhanced emission strength. However, D2 mentions only to a rare earth metal element-containing phosphor which contains Y, for instance, Ba_{0.495}Sr_{2.5}Eu_{0.005})MgSi₂O₈ (Y:1,800 ppm).

D2 furthermore describes that the above-mentioned phosphor is employable as a blue light-emitting source in electron ray excitation light-emitting elements, ultraviolet ray excitation light-emitting elements, vacuum ultraviolet ray excitation light-emitting elements and white light-emitting LEDs. D2 teaches that a phosphor layer prepared by spreading a phosphor paste comprising the above-mentioned phosphor and an organic material on a substrate and heating the coated paste to, for instance, a temperature in the range of 300° C. to 600° C. gives a light emission having enhanced emission strength. D2 refers to light emitting elements such as plasma display panel, field emission display and high intensity fluorescent lamp whose phosphor layer can be manufactured by the heat treatment of the phosphor paste. In the working examples, a light having a wavelength of 146 nm is employed as an excitation light for measuring an emission strength of a phosphor. Accordingly, the excitation light has the same wavelength as that of the vacuum ultraviolet light which is emitted by discharge of Xe gas employed for plasma display.

The white light-emitting LED is a light-emitting device which generally comprises a combination of a semiconductor element emitting a light having a wavelength in the region of 350 to 430 nm (ultraviolet rays to violet rays) by application of electric energy and phosphors emitting visible light by excitation with the light emitted by the semiconductor element. The phosphor comprises a blue light-emitting phosphor, a green light-emitting phosphor and a red light-emitting phosphor. The white light is produced by combining blue light, green light and red light emitted from these phosphors. Therefore, it is required that the blue light-emitting SMS phosphor employed in the white light-emitting LED gives light emission having enhanced emission strength when it is excited with a light having a wavelength in the region of 350 to 430 nm.

Although D1 discloses a blue light-emitting SMS phosphor, there are given no descriptions concerning excitation with a light having a wavelength in the region of 350 to 430 nm. D2 contains no mention with respect to a blue light-emitting SMS phosphor.

### SUMMARY OF THE INVENTION

The object of the invention is to provide an SMS phosphor which emits blue light having enhanced emission strength when it is excited with a light having a wavelength in the region of 350 to 430 nm and therefore it is of value as the phosphor employed for a white light-emitting LED. The invention further provides a light-emitting device employing the blue light-emitting SMS phosphor.

The inventors of the invention have found that a blue light-emitting Eu-activated silicate phosphor having a constitutional formula of Sr₃MgSi₂O₈ which contains Eu in an amount of 0.001 to 0.2 mole per one mol of Mg (this means one mol of the phosphor) and further a rare earth metal element selected from the group consisting of Sc, Y, Gd, Tb and La in the specifically determined amount, gives an emission with enhanced emission strength when it is excited with a light having a wavelength region of 350 to 430 nm.

Accordingly, there is provided by the invention a blue light-emitting Eu-activated silicate phosphor having a constitutional formula of Sr₃MgSi₂O₈ containing Eu in an amount of 0.001 to 0.2 mol per one mol of Mg and a rare earth metal element selected from the group consisting of Sc, Y, Gd, Tb and La in an amount of 0.0001 to 0.03 mol, per one mole of Mg, said Eu-activated silicate phosphor emitting a blue light when it is excited with a light having a wavelength region of 350 to 430 nm.

Preferred embodiments of the above-mentioned blue light-emitting phosphor are described below.

(1) Eu is contained in an amount of 0.01 to 0.2 mol, per one mole of Mg.

(2) Eu is contained in an amount of 0.01 to 0.15 mol, per one mole of Mg.

(3) Eu is contained in an amount of 1 or more in terms of molar ratio, to the amount of the rare earth metal element.

(4) The rare earth metal element is contained in an amount of 0.0005 to 0.02 mol, per one mole of Mg.

There is further provided by the invention a light-emitting device comprising the blue light-emitting phosphor and a semiconductor element emitting a light having a wavelength in the region of 350 to 430 nm by applying electric power thereto.

There is furthermore provided by the invention a light-emitting device comprising the above-mentioned blue light-emitting phosphor, a phosphor emitting a green light when excited with a light having a wavelength in the region of 350 to 430 nm, a phosphor emitting a red light when excited with a light having a wavelength in the region of 350 to 430 nm, and a semiconductor element emitting a light having a wavelength in the region of 350 to 430 nm by applying electric power thereto.

### Effects of the Invention

The blue light-emitting SMS phosphor of the invention emits a light having enhanced emission strength when it is excited with a light having a wavelength in the region of 350 to 430 nm, and hence is of value as a blue light-emitting source for light-emitting devices equipped with an excitation source giving a light emission having a wavelength in the region of 350 to 430 nm.

### BRIEF DESCRIPTION OF DRAWING

FIGURE is a sectional view of a light-emitting device according to the invention.

### EMBODIMENTS OF THE INVENTION

The blue light-emitting SMS phosphor of the invention is a silicate phosphor having a constitutional formula of Sr₃MgSi₂O₈ and containing Eu and a rare earth metal element selected from the group consisting of Sc, Y, Gd, Tb and La, as activators.

Eu is mostly divalent and placed in the Sr site of Sr₃MgSi₂O₈. Eu is contained in an amount of generally 0.001 to 0.2 mol, preferably 0.01 to 0.2 mol, more preferably 0.01 to 0.15 mol, most preferably 0.02 to 0.10 mol per one mol of Mg. Eu is generally contained in a molar ratio of 1 or more, preferably 1 to 300, more preferably 2 to 100, per the amount of the rare earth metal element, that is, Eu/rare earth metal element.

The rare earth metal element is contained in the crystal structure of the blue light-emitting SMS phosphor. The rare earth metal element may be placed in any sites, namely, Sr site, Mg site, and Si site, of Sr₃MgSi₂O₈. The amount of the rare earth metal element can be in the range of generally 0.0001 to 0.03 mol, preferably 0.0005 to 0.02 mol, more preferably 0.0008 to 0.02 mol, per one mole of Mg. The rare earth metal elements can be contained alone or in combination.

The blue light-emitting SMS phosphor of the invention may contain Ba and Ca, provided that the content of Ba should be generally 0.4 mol or less, preferably 0.2 mol or less, more preferably 0.08 mol or less, most preferably 0.01 mol or less, per one mol of Mg, and the content should be generally 0.08 mol or less, preferably 0.01 mol or less, per one mole of Mg.

The blue light-emitting SMS phosphor of the invention can be heated in the presence of ammonium fluoride, whereby the surface of the phosphor can be treated with gaseous ammonium fluoride or its decomposition gas. It has been found that the blue light-emitting SMS phosphor heated in the presence of ammonium fluoride is made resistant to lowering emission characteristics (i.e., emission strength), and further is improved in its humidity resistance, whereby the SMS phosphor shows less lowering of the emission strength when it is brought into contact with water.

The heat treatment of the SMS phosphor in the presence of ammonium fluoride can be carried out by heating a mixture of the SMS phosphor and powdery ammonium fluoride. The mixture comprises generally 0.1 to 15 weight parts, preferably 1 to 10 weight parts of powdery ammonium fluoride per 100 weight parts of the SMS phosphor. The mixture is generally heated to temperatures in the range of 200 to 600° C., preferably in the range of 300 to 600° C., more preferably in the range of 300 to 500° C. The heating is generally carried out for 1 to 5 hours under gaseous conditions such as atmospheric condition, nitrogen gas-condition, or argon gas condition. The heating is preferably carried out under atmospheric condition. In the heating, the phosphor is preferably heated in a heat-resistant crucible which is covered with a lid.

The blue light-emitting SMS phosphor of the invention can be prepared by mixing powdery Sr source, powdery Mg source, powdery Si source, powdery Eu source and powdery rare earth metal source and calcining the resulting powdery mixture. These powdery sources can be powders of oxide powders, hydroxide powders, halide powders, carbonate powders (including basic carbonate powders), nitrate powders, oxalate powders or powders of other materials which are converted into oxides by heating. Each powder can be employed alone or in combination. The powdery source preferably has a purity of 99 wt. % or higher.

The powdery Sr source, powdery Mg source, powdery Si source, powdery Eu source and powdery rare earth metal element are mixed under such conditions that a total amount of Sr, Eu and rare earth metal element is in the range of 2.9 to 3.1 mols, the amount of Si is in the range of 1.9 to 2.1 mols, the amount of Eu is in the range of 0.001 to 0.2 mol, and the amount of rare earth metal element is in the range of 0.0001 to 0.03 mol, per one mole of Mg.

The powdery source mixture may contain flux. The flux preferably is a halide, more preferably chloride. The flux compound preferably is incorporated as a portion of the powdery sources. It is specifically preferred to use powdery strontium chloride. The flux is preferably employed in an amount of 0.0001 to 0.5 mol, more preferably 0.02 to 0.5 mol, per 3 mols of strontium and europium in total.

The powdery sources can be mixed to give a mixture by any one of dry mixing procedures and wet mixing procedures. The wet mixing procedures can be performed by means of a rotating ball mill, a vibrating ball mill, a planetary mill, a paint shaker, a rocking mill, a rocking mixer, a bead mill, or a stirrer. In the wet mixing procedure, solvents such as water and lower alcohols such as ethanol and isopropyl alcohol.

The mixture of the powdery sources is calcined under reducing atmosphere comprising 0.5 to 5.0 vol. % of hydrogen and 99.5 to 95.0 vol. % of inert gas. The inert gas can be argon or nitrogen. The calcination is generally carried out at a temperature in the range of 900 to 1,300° C., for 0.5 to 100 hours.

If the powdery source is powdery material which is converted into oxide by heating, the powdery source is preferably calcined by heating to 600 to 850° C. for 0.5 to 100 hours under atmospheric condition, before the calcination under reducing conditions is performed. The SMS phosphor obtained by the calcination can be sieved, treated with an acid such as hydrochloric acid or nitric acid or baked.

The white light-emitting device of the invention employing the blue light-emitting SMS phosphor is described below referring to the sectional view shown in FIGURE.

FIGURE is a sectional view of an example of the light-emitting device of the invention. The light-emitting device shown in FIGURE is a white light-emitting LED employing the triple color mixing system. In FIGURE, the white light-emitting LED comprises substrate 1, light-emitting semiconductor element 3 fixed on the substrate 1 via adhesive 2, a pair of electrodes 4a,4b formed on the substrate 1, lead wires 5a,5b electrically connecting the semiconductor element 3 to the electrodes 4a,4b, resinous layer 6 coating the semiconductor element 3, phosphor-containing resin composition layer 7 placed on the resinous layer 6, light reflection material 8 surrounding both of the resinous layer 6 and phosphor-containing resin composition layer 7, and conductive wires 9a,9b connecting the electrodes 4a,4b to outside electric source (not shown).

The substrate 1 preferably has high insulating property and high heat conductivity. Examples of the substrate 1 include a substrate of ceramic material such as alumina or aluminum nitride and a resinous substrate containing particles of inorganic material such as metal oxide or ceramic glass.

The light-emitting semiconductor element 3 preferably emits a light having wavelength in the region of 350 to 430 nm by application of electric energy. Examples of the semiconductor element 3 include a light-emitting AlGaN semiconductor element.

The resinous layer 6 is made of transparent resin. Examples of the transparent resin include epoxy resin and silicone resin.

The phosphor-containing resin composition layer 7 comprises a blue light-emitting SMS phosphor, a green light-emitting phosphor and a red light-emitting phosphor dispersed in the resinous binder. Examples of the green light-emitting phosphors include (Ca, Sr, Ba)₂SiO₄:Eu²⁺, BaMgAl₁₀O₁₇:Eu²⁺, Mn²⁺, α-SiAlONL:Eu²⁺, β-SiAlOn:Eu²⁺ and ZnS:Cu, Al. Examples of the red light-emitting phosphors include Y₂O₂S:Eu²⁺, La₂O₃S:Eu²⁺, (Ca, Sr, Br)₂Si₅N₈: Eu²⁺, CaAlSiN₃:Eu²⁺, Eu₂W₂O₉, (Ca, Sr, Ba)₂Si₅M₉:Eu²⁺, Mn²⁺, CaTiO₃:Pr³⁺, Bi³⁺, and (La, Eu)₂W₃O₁₂.

The light-reflecting material 8 reflects visible light produced in the phosphor layer 7 towards the outside and hence the emission efficiency is increased. The light-reflecting material 8 is metals such as Al, Ni, Fe, Cr, Ti, Cu, Rh, Ag, Au and Pt, and white metal compounds or white pigments such as alumina, zirconia, titania, magnesia, zinc oxide and calcium carbonate dispersed in a resinous material.

In the white light-emitting LED of FIGURE, when electric current is applied to the electrodes 4a, 4b via wires 9a, 9b, the semiconductor element 3 emits a light having a emission peak in the wavelength region of 350 to 430 nm. The thus produced emission excites the phosphors in the phosphor-containing resinous layer 7, whereby blue light, green-light and red-light are produced. The thus produced blue-light, green-light and red-right are combined to give a white light.

The white light-emitting LED can be manufactured by the following procedures: the electrodes 4a, 4b are formed on the substrate 1 in the predetermined pattern; the semiconductor light-emitting element 3 is then fixed onto the substrate 1 via an adhesive 2; the semiconductor light-emitting element 3 is connected electrically to the electrodes 4a, 4b via lead wires 5a, 5b by the wire bonding procedure. In the next step, a light-reflecting material 8 is fixed around the semiconductor light-emitting element 3, and a transparent resinous material is placed on the semiconductor light-emitting element 3. The transparent resinous material is cured to form a resin layer 6. Over the resin layer 6, a phosphor-containing resin composition is placed and cured, to form a phosphor-containing layer 7.

### EXAMPLES

### Example 1

Each of powdery strontium carbonate (SrCO₃, purity: 99.7 wt. %, mean particle size determined by laser diffraction scattering: 0.9 μm), powdery strontium chloride hexahydrates (SrCl₂.6H₂O, purity: 99 wt. %), powdery europium oxide (Eu₂O₃, purity: 99.9 wt. %, mean particle size determined by laser diffraction scattering: 2.7 μm), powdery scandium oxide (Sc₂O₃, purity: 99.9 wt. %), powdery magnesium oxide (MgO, prepared by gas phase oxidation method, purity: 99.98 wt. %, particle size calculated from BET specific surface area: 0.2 μm) and powdery silicon dioxide (SiO₂, purity: 99.9 wt. %, particle size calculated from BET specific surface area: 0.01 μm) were weighed to give a molar ratio of 2.804:0.125:0.035:0.0005:1:2.000 for SrCO₃:SrCl₂.6H₂O:Eu₂O₃:Sc₂O₃:MgO:SiO₂. The weighed powders were placed in a ball mill and mixed for 15 hours in the presence of water, to give a slurry of the powdery source mixture. The slurry was spray dried by means of a spray dryer to give a powdery source mixture having a mean particle size of 40 μm. The resulting powdery source mixture was placed in an alumina crucible and calcined to 800° C. for 3 hours under atmospheric conditions. The calcined mixture was allowed to cool to room temperature, and subsequently calcined to 1,200° C. for 3 hours in an atmosphere of gaseous mixture (2 vol. % hydrogen-98 vol. % argon), to obtain a blue light-emitting SMS phosphor. In Table 1, the constitutional formula of the SMS phosphor and its emission strength determined by the below-described procedure. The constitutional formula was determined from the ratio of the powdery sources. The SMS phosphor can be represented by Sr_{3-x-y}EuₓLn_{y}MgSi₂O₈ if the amount of Eu per one mol of the phosphor and the amount of Ln (Ln: rare earth metal element selected from the group consisting of Sc, Y, Gd, Tb and La) per one mol of the phosphor are x and y, respectively.

### [Determination of Emission Strength]

Ultraviolet rays having a wavelength of 400 nm (from Xenon lamp) is applied to the SMS phosphor, to obtain the emission spectrum. The maximum peak strength is determined in the wavelength region of 400 to 500 nm, to give the emission strength. The emission strength is described in terms of a value relative to the emission strength (100) of the SMS phosphor prepared in the below-described Comparison Example 1.

### Example 2

The procedures of Example 1 were repeated using powdery yttrium oxide (Y₂O₃, purity: 99.9 wt. %) in place of the powdery scandium oxide and mixing the powdery sources in a molar ratio of 2.804:0.125:0.035:0.0005:1:2.000 for SrCO₃:SrCl₂.6H₂O:Eu₂O₃:Y₂O₃:MgO:SiO₂, to prepare a blue light-emitting SMS phosphor. In Table 1, the constitutional formula of the SMS phosphor and its emission strength determined by the above-described procedure.

### Example 3

The procedures of Example 2 were repeated except that the powder sources were mixed in a molar ratio of 2.802:0.125:0.035:0.0015:1:2.000 for SrCO₃:SrCl₂.6H₂O:Eu₂O₃:Y₂O₃:MgO:SiO₂, to prepare a blue light-emitting SMS phosphor. In Table 1, the constitutional formula of the SMS phosphor and its emission strength determined by the above-described procedure.

### Example 4

The procedures of Example 2 were repeated except that the powder sources were mixed in a molar ratio of 2.800:0.125:0.035:0.0025:1:2.000 for SrCO₃:SrCl₂.6H₂O:Eu₂O₃:Y₂O₃:MgO:SiO₂, to prepare a blue light-emitting SMS phosphor. In Table 1, the constitutional formula of the SMS phosphor and its emission strength determined by the above-described procedure.

### Example 5

The procedures of Example 1 were repeated using powdery gadolinium oxide (Gd₂O₃, purity: 99.9 wt. %) in place of the powdery scandium oxide and mixing the powdery sources in a molar ratio of 2.804:0.125:0.035:0.0005:1:2.000 for SrCO₃:SrCl₂.6H₂O:Eu₂O₃:Gd₂O₃:MgO:SiO₂, to prepare a blue light-emitting SMS phosphor. In Table 1, the constitutional formula of the SMS phosphor and its emission strength determined by the above-described procedure.

### Example 6

The procedures of Example 5 were repeated except that the powder sources were mixed in a molar ratio of 2.802:0.125:0.035:0.0015:1:2.000 for SrCO₃:SrCl₂.6H₂O:Eu₂O₃:Gd₂O₃:MgO:SiO₂, to prepare a blue light-emitting SMS phosphor. In Table 1, the constitutional formula of the SMS phosphor and its emission strength determined by the above-described procedure.

### Example 7

The procedures of Example 1 were repeated using powdery terbium oxide (Tb₂O₃, purity: 99.9 wt. %) in place of the powdery scandium oxide and mixing the powdery sources in a molar ratio of 2.804:0.125:0.035:0.0005:1:2.000 for SrCO₃:SrCl₂.6H₂O:Eu₂O₃:Tb₂O₃:MgO:SiO₂, to prepare a blue light-emitting SMS phosphor. In Table 1, the constitutional formula of the SMS phosphor and its emission strength determined by the above-described procedure.

### Example 8

The procedures of Example 7 were repeated except that the powder sources were mixed in a molar ratio of 2.800:0.125:0.035:0.0025:1:2.000 for SrCO₃:SrCl₂.6H₂O:Eu₂O₃:Tb₂O₃:MgO:SiO₂, to prepare a blue light-emitting SMS phosphor. In Table 1, the constitutional formula of the SMS phosphor and its emission strength determined by the above-described procedure.

### Example 9

The procedures of Example 7 were repeated except that the powder sources were mixed in a molar ratio of 2.795:0.125:0.035:0.0050:1:2.000 for SrCO₃:SrCl₂.6H₂O:Eu₂O₃:Tb₂O₃:MgO:SiO₂, to prepare a blue light-emitting SMS phosphor. In Table 1, the constitutional formula of the SMS phosphor and its emission strength determined by the above-described procedure.

### Example 10

The procedures of Example 1 were repeated using powdery lanthanum oxide (La₂O₃, purity: 99.9 wt. %) in place of the powdery scandium oxide and mixing the powdery sources in a molar ratio of 2.800:0.125:0.035:0.0025:1:2.000 for SrCO₃:SrCl₂.6H₂O:Eu₂O₃:La₂O₃:MgO:SiO₂, to prepare a blue light-emitting SMS phosphor. In Table 1, the constitutional formula of the SMS phosphor and its emission strength determined by the above-described procedure.

### Comparison Example 1

The procedures of Example 1 were repeated using no powdery scandium oxide and mixing the powdery sources in a molar ratio of 2.805:0.125:0.035:1:2.000 for SrCO₃:SrCl₂.6H₂O:Eu₂O₃:MgO:SiO₂, to prepare a blue light-emitting SMS phosphor. In Table 1, the constitutional formula of the SMS phosphor and its emission strength determined by the above-described procedure.

TABLE 1

| | Constitutional formula | Emission strength |
|---|---|---|
| Example 1 | Sr_{2.929}Eu_{0.07}Sc_{0.001}MgSi₂O₈ | 105 |
| Example 2 | Sr_{2.929}Eu_{0.07}Y_{0.001}MgSi₂O₈ | 104 |
| Example 3 | Sr_{2.927}Eu_{0.07}Y_{0.003}MgSi₂O₈ | 104 |
| Example 4 | Sr_{2.925}Eu_{0.07}Y_{0.005}MgSi₂O₈ | 111 |
| Example 5 | Sr_{2.929}Eu_{0.07}Gd_{0.001}MgSi₂O₈ | 111 |
| Example 6 | Sr_{2.927}Eu_{0.07}Gd_{0.003}MgSi₂O₈ | 102 |
| Example 7 | Sr_{2.929}Eu_{0.07}Tb_{0.001}MgSi₂O₈ | 109 |
| Example 8 | Sr_{2.925}Eu_{0.07}Tb_{0.005}MgSi₂O₈ | 110 |
| Example 9 | Sr_{2.920}Eu_{0.07}Tb_{0.010}MgSi₂O₈ | 121 |
| Example 10 | Sr_{2.925}Eu_{0.07}La_{0.005}MgSi₂O₈ | 107 |
| Com. Ex. 1 | Sr_{2.930}Eu_{0.07}MgSi₂O₈ | 100 |

As is clear from the results shown in Table 1, the blue light-emitting SMS phosphors containing Sc, Y, Gd, Tb or La in the range of the invention (Examples 1 to 10) gives a higher emission strength when it is excited with ultraviolet rays (wavelength: 400 nm), as compared with the SMS phosphor containing no rare earth metal element (Comparison Example 1).

### Example 11

### (1) Heat Treatment in the Presence of Ammonium Fluoride

5 weight parts of ammonium fluoride were mixed with 100 weight parts of the blue light-emitting SMS phosphor prepared in Example 4, to give a powdery mixture. The powdery mixture was placed in an alumina crucible, and covered with a lid. The alumina crucible was heated to 500° C. for 6 hours under atmospheric conditions, and then allowed to cool to room temperature. The cooled SMS phosphor was subjected to determination of the emission strength by exciting the phosphor with ultraviolet rays (wavelength: 400 nm), in the aforementioned manner. The determined emission strength is set forth in Table 2.

The cooled SMS phosphor was sectioned to observe the section of the surface layer by means of TEM (Transmissive Electron Microscope). It was found that the surface of th phosphor had a covering layer.

### (2) Determination of Emission Strength after Storage in High Temperature-High Humidity Conditions (Evaluation of Moisture Resistance)

The SMS phosphor having been subjected to heat treatment in the presence of ammonium fluoride in the procedure (1) above was placed in a thermostat and allowed to stand at 60° C., RH90% for 720 hours. The SMS phosphor subjected to this procedure was determined in its emission strength by exciting it with ultraviolet rays (wavelength: 400 nm) in the aforementioned manner. The results are set forth in Table 2, together with the emission strength determined before the phosphor was kept under high temperature-high humidity conditions.

### Example 12

The SMS phosphor prepared in Example 4 was placed in a thermostat and allowed to stand at 60° C., RH90% for 720 hours. The SMS phosphor subjected to this procedure was determined in its emission strength by exciting it with ultraviolet rays (wavelength: 400 nm) in the aforementioned manner. The results are set forth in Table 2, together with the emission strength determined before the phosphor was kept under high temperature-high humidity conditions.

### Comparison Example 2

The SMS phosphor prepared in Comparison Example 1 was placed in a thermostat and allowed to stand at 60° C., RH90% for 720 hours. The SMS phosphor subjected to this procedure was determined in its emission strength by exciting it with ultraviolet rays (wavelength: 400 nm) in the aforementioned manner. The results are set forth in Table 2, together with the emission strength determined before the phosphor was kept under high temperature-high humidity conditions.

TABLE 2

| | Before heat treatment | After heat treatment |
|---|---|---|
| Example 11 | 111 | 114 |
| Example 12 | 111 | 94 |
| Com. Ex. 2 | 100 | 85 |

### Remarks:

Before heat treatment: Before storage under high temperature-high humidity conditions

After heat treatment: After storage under high temperature-high humidity conditions

As is clear from the results set forth in Table 2, the blue light-emitting SMS phosphor of the invention (Example 12) shows a higher emission strength when it is kept under the high temperature-high humidity conditions, as compared with the SMS phosphor containing no rare earth metal element (Comparison Example 2). It is noted that the SMS phosphor subjected to heat treatment in the presence of ammonium fluoride (Example 11) showed increased emission strength after being kept under high temperature-high humidity conditions.

### EXPLANATION OF SYMBOLS

1 substrate
2 adhesive
3 light-emitting semiconductor element
4a,4b electrode
5a,5b lead wire
6 resinous layer
7 phosphor layer
8 light-reflecting material
9a,9b conductive wire

What is claimed is:

1. A blue light-emitting Eu-activated silicate phosphor having a constitutional formula of Sr₃MgSi₂O₈ containing Eu in an amount of 0.001 to 0.2 mol per one mole of Mg and a rare earth metal element selected from the group consisting of Sc, Y, Gd, Tb and La in an amount of 0.0001 to 0.03 mol, per one mole of Mg, said Eu-activated silicate phosphor emitting a blue light when it is excited with a light having a wavelength region of 350 to 430 nm.
